(19) United States
(12) Patent Application Publication
(10) Pub. No.: US 2010/0325511 A1
(43) Pub. Date: Dec. 23, 2010

(54) METHOD OF GENERATING PARITY-CHECK MATRIX, ENCODING/DECODING METHOD FOR LOW DENSITY PARITY-CHECK CODE WITH VARIABLE INFORMATION LENGTH AND VARIABLE CODE RATE AND APPARATUS USING THE SAME

(76) Inventors: Jong-Ee Oh, Daejeon-city (KR); Chanho Yoon, Daejeon-city (KR); Minho Cheong, Daejeon-city (KR); Yu-Ro Lee, Daejeon-city (KR); Sok-Kyu Lee, Daejeon-city (KR); Heejung Yu, Daejeon-city (KR); Seung-Chan Bang, Daejeon-city (KR)

Correspondence Address: STAAS & HALSEY LLP, SUITE 700, 1201 NEW YORK AVENUE, N.W., WASHINGTON, DC, 20005, US

(21) Appl. No.: 12/517,763

(22) PCT Filed: Oct. 31, 2007
(86) PCT No.: PCT/KR07/05478

§ 371 Date: Jun. 4, 2009

(30) Foreign Application Priority Data
Dec. 5, 2006 (KR) 10-2006-0122624
Mar. 6, 2007 (KR) 10-2007-0021965

(51) Int. Cl. H03M 13/05; G06F 11/10

(52) U.S. Cl. 714/752; 714/E11.032; 714/790

(57) ABSTRACT

A method of generating a parity-check matrix of a low density parity-check (LDPC) code with a variable information length and a variable code rate, an encoding/decoding method, and an apparatus using the same are provided. The method of generating a parity-check matrix of an LDPC code includes: a first parity-check matrix generation process of generating a first parity-check matrix constructed with a first information block and a parity block; and an m-th parity-check matrix generation process of generating an m-th parity-check matrix by an m-th information block to a generated (m−1)-th parity-check matrix (1<m≦M, where M is a natural number equal to or greater than two). Accordingly, it is possible to provide an LDPC code with a variable information length and a variable code rate which has a low complexity for encoding/decoding and a high quality of correction and detection of errors.

### TECHNICAL FIELD

The present invention relates to an error correction code of a wired/wireless communication system, and more particularly, to a method of generating a parity-check matrix, an encoding/decoding method for a low density parity-check (hereinafter, abbreviated to LDPC) code with a variable information length and a variable code rate, and an apparatus using the same.

This work was supported by the IT R&D program of MIC/IITA (Ministry of Information and Communication/Institute for Information Technology Advancement). [2006-S-002-01, IMT-Advanced Radio Transmission Technology with Low Mobility]

This application claims the benefit of Korean Patent Application No. 10-2006-0122624, filed on Dec. 5, 2006 and Korean Patent Application No. 10-2007-0021965, filed on Mar. 6, 2007 in the Korean Intellectual Property Office, the disclosures of which are incorporated herein in their entirety by reference.

### BACKGROUND ART

A transmitted signal in a wired/wireless communication system suffers noise, interference, and fading in a transmission channel. Thus, a case occurs where a receiving end cannot demodulate the transmitted signal.

A typical technique from among various techniques used to reduce an occurrence rate of an error which increases as a transmission speed increases is the use of an error correction code. Recently, the error correction code has been applied to most wireless communication systems. Specifically, a low density parity-check (LDPC) code has been spotlighted for a next generation high capacity wireless communication system, because the LDPC code has high-performance error correction and can embody a high speed decoder with low complexity.

Methods of decoding the LDPC code include a decoding method which employs a serial or partially parallel processing technique and a decoding method which employs a parallel processing technique. The former method has an advantage in that the size of hardware is reduced by repeatedly using a few variable node processing blocks for common use and a few check node processing blocks for common use, but has a disadvantage in that the method cannot support high speed decoding. On the other hand, the latter method can support high speed decoding by performing a parallel information exchange by including a variable node processing block and a check node processing block optimized for each parity-check matrix. However, the latter method has a disadvantage in that the size of hardware is big and a disadvantage in that the hardware size increases as various code rates are supported.

On the other hand, the wired/wireless communication system needs to use an error correction code with a variable information length and a variable code rate so as to perform a hybrid automatic repeat request (H-ARQ) or to apply a modulation and coding scheme (hereinafter, abbreviated to MCS) that is adaptive for a channel state. Conventional decoding methods used to support various MCS levels so as to meet the aforementioned needs include a method of separately embodying decoders optimized for information lengths and code rates and a method of using a piece of hardware and using information shortening or puncturing techniques. However, the former method has a disadvantage in that the size of the hardware increases. The latter method has a disadvantage in that a random application of the information shortening or parity puncturing techniques causes a serious deterioration of the error correction performance of the LDPC code.

As described above, a parallel processing decoding method is advantageous for a super high speed wireless communication system that requires a processing speed of gigabytes. In order to effectively apply a recently spotlighted adaptive modulation and coding scheme, the LDPC code is required, with high-performance error correction which supports a variable information length and a variable code rate. In addition, the encoding/decoding complexity of the LDPC code has to be low.

### DISCLOSURE OF INVENTION

### Technical Problem

Accordingly, the LDPC code is required, with high-performance error correction, which can easily embody a decoder with a variable information length and a variable code rate by using only a piece of parallel processing hardware and can reduce encoding complexity. For this, a method of generating a parity-check matrix corresponding to the LDPC code, an encoding/decoding method, and an apparatus using the same are required.

### Technical Solution

The present invention provides a low density parity-check (LDPC) code having high-performance error correction, which supports low encoding/decoding complexity, high speed decoding, a variable information length, and a variable code rate, a method of generating a parity-check matrix of the LDPC code, an encoding/decoding method, and apparatus using the same.

### ADVANTAGEOUS EFFECTS

It is possible to easily embody a decoder with a variable information length and a variable code rate by using only a piece of parallel processing hardware and to perform super high speed decoding.

In addition, it is possible to generate an LDPC code with high-performance error correction which supports a variable information length and a variable code rate.

In addition, it is possible to generate an LDPC code with reduced encoding complexity which supports a variable information length and a variable code rate.

### DESCRIPTION OF DRAWINGS

The above and other features and advantages of the present invention will become more apparent by describing in detail exemplary embodiments thereof with reference to the attached drawings in which:

FIG. 1 illustrates examples of 5×5 cyclic-permutation matrices;

FIG. 2 illustrates a table including low density parity-check (LDPC) matrices according to an embodiment of the present invention;

FIG. 3 schematically illustrates relations among parity-check matrices exemplified in the table of FIG. 2;

FIG. 4 illustrates an example of a parity-check matrix with a parity length of 456 bits which supports five code rates;

FIG. 5 illustrates an example of a matrix P¹ that is a parity block included in the parity-check matrix of FIG. 4;

FIGS. 6 to 10 respectively illustrate examples of first to five information blocks C¹₀, C¹₁, C¹₂, C¹₃, and C¹₄ of FIG. 4;

FIGS. 11 to 13 respectively illustrate examples of parity-check matrices with parity lengths of 912, 1368, and 1824 bits which support five code rates;

FIG. 14 illustrates an equation which represents a row-splitting technique according to an embodiment of the present invention;

FIG. 15 illustrates a concept whereby an information shortening technique and a puncturing technique are applied to a parity-check matrix;

FIGS. 16 and 17 are block diagrams illustrating structures of an apparatus for generating a parity-check matrix according to an embodiment of the present invention;

FIG. 18 is a block diagram illustrating an LDPC encoding apparatus which supports a variable information length and a variable code rate according to an embodiment of the present invention;

FIG. 19 is a block diagram illustrating an LDPC decoding apparatus which supports a variable information length and a variable code rate according to an embodiment of the present invention;

FIGS. 20 and 21 are flowcharts illustrating a method of generating a parity-check matrix according to an embodiment of the present invention;

FIG. 22 is a flowchart illustrating an LDPC encoding method which supports a variable information length and a variable code rate according to an embodiment of the present invention; and

FIG. 23 is a flowchart illustrating an LDPC decoding method which supports a variable information length and a variable code rate according to an embodiment of the present invention.

### BEST MODE

According to an aspect of the present invention, there is provided a method of generating a parity-check matrix of an LDPC (low density parity-check) code with a variable information length and a variable code rate, the method comprising: a first parity-check matrix generation process of generating a first parity-check matrix constructed with a first information block and a parity block; and an m-th parity-check matrix generation process of generating an m-th parity-check matrix by adding an m-th information block to a generated (m−1)-th parity-check matrix (1<m≦M, where M is a natural number equal to or greater than two).

The m-th (1≦m≦M) parity-check matrix generation process may include a process of generating the m-th parity-check matrix by performing optimization of degree distribution and cycle distribution.

The method may further comprise an information shortening process of generating at least one parity-check matrix which is different from the first to M-th parity-check matrices by applying an information shortening technique to at least one of the first to M-th parity-check matrices.

The method may further comprise a puncturing process of generating at least one parity-check matrix which is different from the first to M-th parity-check matrices by applying a puncturing technique to at least one of the first to M-th parity-check matrices.

The puncturing process may include a process of performing the puncturing technique with respect to an information block. The puncturing process may include a process of performing the puncturing technique with respect to the parity block.

According to another aspect of the present invention, there is provided a method of generating a parity-check matrix of an LDPC (low density parity-check) code with a variable information length and a variable code rate, the method comprising: a basic parity-check matrix generation process of generating at least one basic parity-check matrix; and an extended parity-check matrix generation process of generating at least one extended parity-check matrix by applying a row-splitting technique to an information block of the basic parity-check matrix and extending a parity block of the basic parity-check matrix.

The basic parity-check matrix generation process may include a process of generating an m-th basic parity-check matrix by generating the first basic parity-check matrix constructed with a first basic information block and a basic parity block and by adding an m-th basic information block to a generated (m−1)-th basic parity-check matrix (1<m≦M, where M is a natural number equal to or greater than two), and wherein the extended parity-check matrix generation process includes a process of generating an m-th extended information block constructed with an extended parity block and first to m-th extended information blocks by generating an extended parity block by extending the basic parity block and by generating the m-th extended information block by applying the row-splitting technique to the m-th basic information block (1≦m≦M).

The extended parity-check matrix generation process may include a process of generating the extended parity block with the same structure as the basic parity block. The basic parity block and the extended parity block may have a double diagonal matrix form.

The basic parity-check matrix generation process may include a process of generating the basic parity-check matrix by performing optimization of degree distribution and cycle distribution, and wherein the extended parity-check matrix generation process includes a process of generating the extended parity-check matrix by performing the optimization of the degree distribution and the cycle distribution.

The method may further comprise an information shortening process of generating at least one parity-check matrix which is different from the basic parity-check matrix and the extended parity-check matrix by applying an information shortening technique to at least one of the basic parity-check matrix and the extended parity-check matrix.

The method may further comprise a puncturing process of generating at least one parity-check matrix which is different from the basic parity-check matrix and the extended parity-check matrix by applying a puncturing technique to at least one of the basic parity-check matrix and the extended parity-check matrix. The puncturing process may include a process of performing the puncturing technique with respect to an information block. The puncturing process may include a process of performing the puncturing technique with respect to the parity block.

According to another aspect of the present invention, there is provided an LDPC encoding method which supports a variable information length and a variable code rate, the LDPC encoding method comprising: a parity-check matrix selection process of selecting a parity-check matrix corresponding to an input encoding parameter from among a plurality of parity-check matrices; and an encoding process of encoding an input information word based on the selected parity-check matrix, wherein the plurality of parity-check matrices include a first parity-check matrix, which is constructed with a first information block and a parity block, and an m-th parity-check matrix, which is obtained by adding an m-th information block to an (m−1)-th parity-check matrix (1<m≦M, where M is a natural number equal to or greater than two).

The input encoding parameter may include a code rate and a length of the input information word.

The plurality of parity-check matrices may further include at least one parity-check matrix generated by applying the information shortening technique to at least one of the first to M-th parity-check matrices.

The plurality of parity-check matrices may further include at least one parity-check matrix generated by applying the puncturing technique to at least one of the first to M-th parity-check matrices.

According to another aspect of the present invention, there is provided an LDPC encoding method which supports a variable information length and a variable code rate, the LDPC encoding method comprising: a parity-check matrix selection process of selecting a parity-check matrix corresponding to an input encoding parameter from among a plurality of parity-check matrices; and an encoding process of encoding an input information word based on the selected parity-check matrix, wherein the plurality of parity-check matrices include at least one basic parity-check matrix and at least one extended parity-check matrix generated by applying a row-splitting technique to an information block of the basic parity-check matrix and extending a parity block of the basic parity-check matrix.

The input encoding parameter may include a code rate and a length of the input information word.

The plurality of parity-check matrices may further include at least one parity-check matrix generated by applying an information shortening technique to at least one of the basic parity-check matrix and the extended parity-check matrix.

The plurality of parity-check matrices may further include at least one parity-check matrix generated by applying a puncturing technique to at least one of the basic parity-check matrix and the extended parity-check matrix.

According to another aspect of the present invention, there is provided an LDPC decoding method which supports a variable information length and a variable code rate, the LDPC decoding method comprising: a parity-check matrix selection process of selecting a parity-check matrix corresponding to an input decoding parameter from among a plurality of parity-check matrices; and a decoding process of decoding a received codeword based on the selected parity-check matrix, wherein the plurality of parity-check matrices include a first parity-check matrix, which is constructed with a first information block and a parity block, and an m-th parity-check matrix, which is obtained by adding an m-th information block to an (m−1)-th parity-check matrix (1<m≦M, where M is a natural number equal to or greater than two).

The input decoding parameter may include a code rate and a length of the received codeword.

The plurality of parity-check matrices may further include at least one parity-check matrix generated by applying the information shortening technique to at least one of the first to M-th parity-check matrices, and wherein the decoding process includes a process of performing decoding by setting a probability that an information-shortened bit has a value of 0 to a value of 1, when the selected parity-check matrix is a matrix to which the information shortening technique is applied.

The plurality of parity-check matrices may further include at least one parity-check matrix generated by applying the puncturing technique to at least one of the first to M-th parity-check matrices, and wherein the decoding process includes a process of performing decoding by setting a probability that a punctured bit has a value of 0 to a value of 0.5, when the selected parity-check matrix is a matrix to which the puncturing technique is applied.

According to another aspect of the present invention, there is provided an LDPC decoding method which supports a variable information length and a variable code rate, the LDPC decoding method comprising: a parity-check matrix selection process of selecting a parity-check matrix corresponding to an input decoding parameter from among a plurality of parity-check matrices; and an encoding process of decoding a received codeword based on the selected parity-check matrix, wherein the plurality of parity-check matrices include at least one basic parity-check matrix and at least one extended parity-check matrix generated by applying a row-splitting technique to an information block of the basic parity-check matrix and extending a parity block of the basic parity-check matrix.

The input decoding parameter may include a code rate and a length of the received codeword.

The plurality of parity-check matrices may further include at least one parity-check matrix generated by applying the information shortening technique to at least one of the first to M-th parity-check matrices, and wherein the decoding process includes a process of performing decoding by setting a probability that an information-shortened bit has a value of 0 to a value of 1, when the selected parity-check matrix is a matrix to which the information shortening technique is applied.

The plurality of parity-check matrices may further include at least one parity-check matrix generated by applying the puncturing technique to at least one of the first to M-th parity-check matrices, and wherein the decoding process includes a process of performing decoding by setting a probability that a punctured bit has a value of 0 to a value of 0.5, when the selected parity-check matrix is a matrix to which the puncturing technique is applied.

According to another aspect of the present invention, there is provided an apparatus for generating a parity-check matrix of an LDPC (low density parity-check) code with a variable information length and a variable code rate, the apparatus comprising: a first parity-check matrix generation unit generating a first parity-check matrix constructed with a first information block and a parity block; and an m-th parity-check matrix generation unit generating an m-th parity-check matrix by adding an m-th information block to a generated (m−1)-th parity-check matrix (1<m≦M, where M is a natural number equal to or greater than two).

The m-th (1≦m≦M) parity-check matrix generation unit may include a unit generating the m-th parity-check matrix by performing optimization of degree distribution and cycle distribution.

The apparatus may further comprise an information shortening unit generating at least one parity-check matrix which is different from the first to M-th parity-check matrices by applying an information shortening technique to at least one of the first to M-th parity-check matrices.

The apparatus may further comprise a puncturing unit generating at least one parity-check matrix which is different from the first to M-th parity-check matrices by applying a puncturing technique to at least one of the first to M-th parity-check matrices.

The puncturing unit may include a unit performing the puncturing technique with respect to an information block. The puncturing unit may include a unit performing the puncturing technique with respect to the parity block.

According to another aspect of the present invention, there is provided an apparatus for generating a parity-check matrix of an LDPC (low density parity-check) code with a variable information length and a variable code rate, the apparatus comprising: a basic parity-check matrix generation unit generating at least one basic parity-check matrix; and an extended parity-check matrix generation unit generating at least one extended parity-check matrix by applying a row-splitting technique to an information block of the basic parity-check matrix and extending a parity block of the basic parity-check matrix.

The basic parity-check matrix generation unit may include a unit generating an m-th basic parity-check matrix by generating the first basic parity-check matrix constructed with a first basic information block and a basic parity block and by adding an m-th basic information block to a generated (m−1)-th basic parity-check matrix (1<m≦M, where M is a natural number equal to or greater than two), and wherein the extended parity-check matrix generation unit includes a unit generating an m-th extended information block constructed with an extended parity block and first to m-th extended information blocks by generating an extended parity block by extending the basic parity block and by generating the m-th extended information block by applying the row-splitting technique to the m-th basic information block (1≦m≦M).

The extended parity-check matrix generation unit may include a unit generating the extended parity block with the same structure as the basic parity block. The basic parity block and the extended parity block may have a double diagonal matrix form.

The basic parity-check matrix generation unit may include a unit generating the basic parity-check matrix by performing optimization of degree distribution and cycle distribution, and wherein the extended parity-check matrix generation unit includes a unit generating the extended parity-check matrix by performing the optimization of the degree distribution and the cycle distribution.

The unit may further comprise an information shortening unit generating at least one parity-check matrix which is different from the basic parity-check matrix and the extended parity-check matrix by applying an information shortening technique to at least one of the basic parity-check matrix and the extended parity-check matrix.

The unit may further comprise a puncturing unit generating at least one parity-check matrix which is different from the basic parity-check matrix and the extended parity-check matrix by applying a puncturing technique to at least one of the basic parity-check matrix and the extended parity-check matrix. The puncturing unit may include a unit performing the puncturing technique with respect to an information block. The puncturing unit may include a unit performing the puncturing technique with respect to the parity block.

According to another aspect of the present invention, there is provided an LDPC encoding apparatus which supports a variable information length and a variable code rate, the LDPC encoding apparatus comprising: a parity-check matrix selection unit selecting a parity-check matrix corresponding to an input encoding parameter from among a plurality of parity-check matrices; and an encoding unit encoding an input information word based on the selected parity-check matrix, wherein the plurality of parity-check matrices include a first parity-check matrix, which is constructed with a first information block and a parity block, and an m-th parity-check matrix, which is obtained by adding an m-th information block to an (m−1)-th parity-check matrix (1<m≦M, where M is a natural number equal to or greater than two).

The input encoding parameter may include a code rate and a length of the input information word.

The plurality of parity-check matrices may further include at least one parity-check matrix generated by applying the information shortening technique to at least one of the first to M-th parity-check matrices.

The plurality of parity-check matrices may further include at least one parity-check matrix generated by applying the puncturing technique to at least one of the first to M-th parity-check matrices.

According to another aspect of the present invention, there is provided an LDPC encoding apparatus which supports a variable information length and a variable code rate, the LDPC encoding apparatus comprising: a parity-check matrix selection unit selecting a parity-check matrix corresponding to an input encoding parameter from among a plurality of parity-check matrices; and an encoding unit encoding an input information word based on the selected parity-check matrix, wherein the plurality of parity-check matrices include at least one basic parity-check matrix and at least one extended parity-check matrix generated by applying a row-splitting technique to an information block of the basic parity-check matrix and extending a parity block of the basic parity-check matrix.

The input encoding parameter may include a code rate and a length of the input information word.

The plurality of parity-check matrices may further include at least one parity-check matrix generated by applying an information shortening technique to at least one of the basic parity-check matrix and the extended parity-check matrix.

The plurality of parity-check matrices may further include at least one parity-check matrix generated by applying a puncturing technique to at least one of the basic parity-check matrix and the extended parity-check matrix.

According to another aspect of the present invention, there is provided an LDPC decoding apparatus which supports a variable information length and a variable code rate, the LDPC decoding apparatus comprising: a parity-check matrix selection unit selecting a parity-check matrix corresponding to an input decoding parameter from among a plurality of parity-check matrices; and a decoding unit decoding a received codeword based on the selected parity-check matrix, wherein the plurality of parity-check matrices include a first parity-check matrix, which is constructed with a first information block and a parity block, and an m-th parity-check matrix, which is obtained by adding an m-th information block to an (m−1)-th parity-check matrix (1<m≦M, where M is a natural number equal to or greater than two).

The input decoding parameter may include a code rate and a length of the received codeword.

The plurality of parity-check matrices may further include at least one parity-check matrix generated by applying the information shortening technique to at least one of the first to M-th parity-check matrices, and wherein the decoding unit includes a unit performing decoding by setting a probability that an information-shortened bit has a value of 0 to a value of 1, when the selected parity-check matrix is a matrix to which the information shortening technique is applied.

The plurality of parity-check matrices may further include at least one parity-check matrix generated by applying the puncturing technique to at least one of the first to M-th parity-check matrices, and wherein the decoding unit includes a unit performing decoding by setting a probability that a punctured bit has a value of 0 to a value of 0.5, when the selected parity-check matrix is a matrix to which the puncturing technique is applied.

According to another aspect of the present invention, there is provided an LDPC decoding apparatus which supports a variable information length and a variable code rate, the LDPC decoding apparatus comprising: a parity-check matrix selection unit selecting a parity-check matrix corresponding to an input decoding parameter from among a plurality of parity-check matrices; and an encoding unit decoding a received codeword based on the selected parity-check matrix, wherein the plurality of parity-check matrices include at least one basic parity-check matrix and at least one extended parity-check matrix generated by applying a row-splitting technique to an information block of the basic parity-check matrix and extending a parity block of the basic parity-check matrix.

The input decoding parameter may include a code rate and a length of the received codeword.

The plurality of parity-check matrices may further include at least one parity-check matrix generated by applying the information shortening technique to at least one of the first to M-th parity-check matrices, and wherein the decoding unit includes a unit performing decoding by setting a probability that an information-shortened bit has a value of 0 to a value of 1, when the selected parity-check matrix is a matrix to which the information shortening technique is applied.

The plurality of parity-check matrices may further include at least one parity-check matrix generated by applying the puncturing technique to at least one of the first to M-th parity-check matrices, and wherein the decoding unit includes a unit performing decoding by setting a probability that a punctured bit has a value of 0 to a value of 0.5, when the selected parity-check matrix is a matrix to which the puncturing technique is applied.

### MODE FOR INVENTION

Hereinafter, a method and apparatus according to an embodiment of the present invention will be described in detail with reference to the attached drawings.

A low density parity-check (LDPC) code is introduced by Gallager. The LDPC code is defined as a parity-check matrix in which a few elements have 1's, and the rest of the elements have 0's.

The LDPC code is largely classified into a regular LDPC code and an irregular LDPC code. The regular LDPC code is suggested by Gallager. All the rows in the parity-check matrix have the same number of 1's, and all the columns also have the same number of 1's. Unlike the regular LDPC code, in the parity-check matrix of the irregular LDPC code, there exist rows having different numbers of 1's, or there exist columns having different numbers of 1's. In general, it is known that the error correction performance of the irregular LDPC code is higher than that of the regular LDPC code.

On the other hand, Fossorier suggests that elements of the parity-check matrix are not 0's or 1's on GF(2), but a quasi-cyclic LDPC code represented by a cyclic shifted identity matrix and a zero matrix (‘Quasi-cyclic low density parity-check codes from circulant permutation matrices,’ IEEE Trans. Inform. Theory, vol. 50, pp. 1788-1794, August 2004).

In this specification, for convenience of explanation, when the quasi-cyclic LDPC code is used, the spirit and scope of the present invention will be described. However, it will be understood by those of ordinary skill in the art that the elements of the parity-check matrix will be also applied to the LDPC code described in G(2), in addition to the quasi-cyclic LDPC code.

In addition, in this specification, for convenience of explanation, the spirit and scope of the present invention will be described by fixing the size of sub-matrices, the number of the sub-matrices, and degree distribution of the parity-check matrix. However, it will be sufficiently understood by those of ordinary skill in the art that a method of changing the size of n×n sub-matrices, a method of changing the number of the sub-matrices to be used, and a method of obtaining an information length and a code rate changed by using an information bit row-splitting technique changed based on the change of the degree distribution of the parity-check matrix are included in the spirit and scope of the present invention.

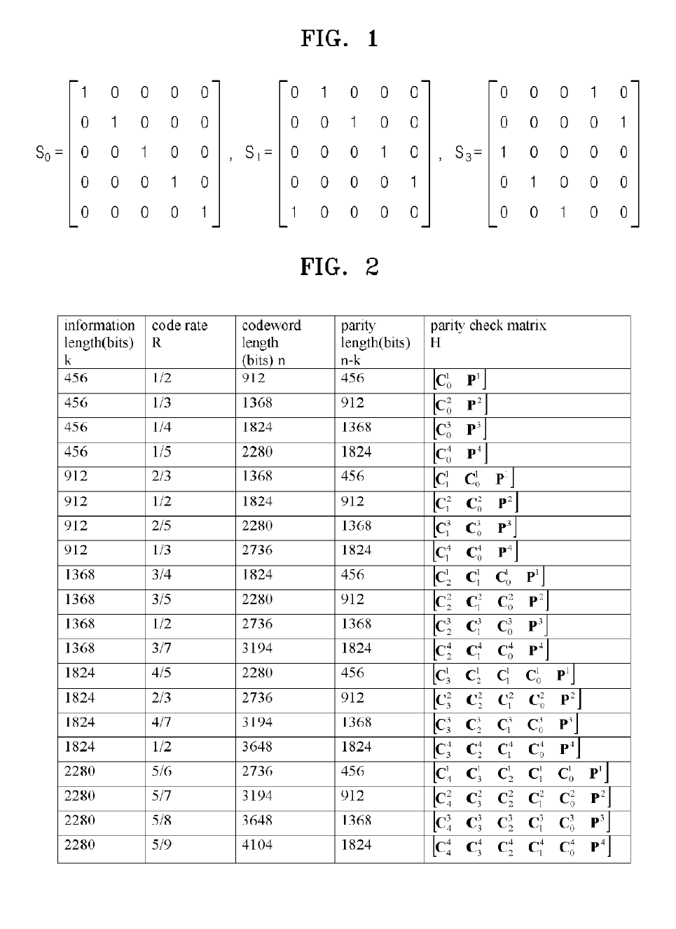

FIG. 1 illustrates examples of 5×5 cyclic-permutation matrices.

As illustrated in FIG. 1, a sub-matrix Si is obtained by cyclically shifting columns of the identity matrix by i in the right side.

Hereinafter, in order to describe the spirit and scope of the present invention, a parity-check matrix constructed with 38×38 sub-matrices is used as an example. In this case, the sub-matrices include a matrix obtained by applying a cyclic shift to a 38×38 identity matrix and a 38×38 zero matrix.

FIG. 2 illustrates a table including LDPC matrices according to an embodiment of the present invention. Twenty LDPC matrices included in the table of FIG. 2 are generated by using a method of generating a parity-check matrix according to the current embodiment of the present invention. It is possible to use combinations of information lengths and parity lengths so as to embody an encoder/decoder that supports twenty types of variable information lengths and variable code rates by using 456, 912, 1368, 1824 and 2280 bits as the information lengths and by using 456, 912, 1368, and 1824 bits as the parity lengths.

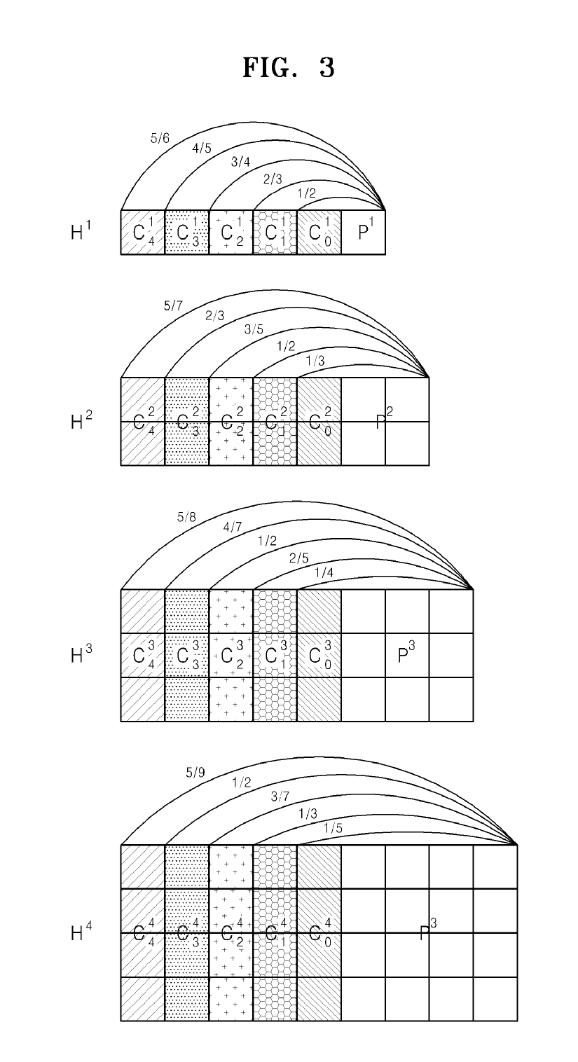

FIG. 3 schematically illustrates relations among parity-check matrices exemplified in the table of FIG. 2.

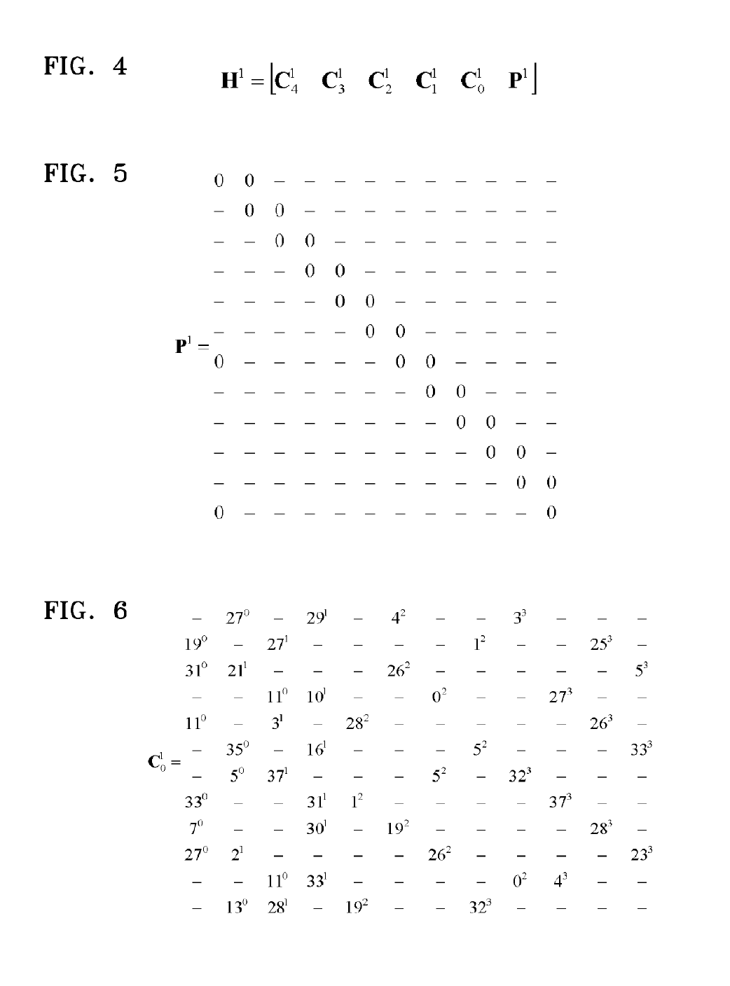

In FIG. 3, a small square is a 456×456 matrix. A Cⁱⱼ block and a Pⁱ block illustrated in FIGS. 2 and 3 respectively indicate an information block and a parity block which constructs the parity-check matrix. A detailed description of this will be given with reference to FIG. 4 and Equation 1.

In the case of the LDPC code, in general, the parity-check matrix with high-performance error correction is generated by using a design optimized for the degree distribution of the parity-check matrix and a design optimized for the cycle distribution on a factor graph. Parity-check matrices used in the present invention will be described later. However, since the parity-check matrices have correlation with one another, designs optimized for all the parity-check matrices have to be concurrently performed, instead of individually performing designs optimized for the parity-check matrices.

FIG. 4 illustrates an example of a parity-check matrix H¹ with a parity length of 456 bits, which supports five code rates. The parity-check matrix H¹ is the parity-check matrix H¹ illustrated in FIG. 3.

FIG. 5 illustrates an example of a matrix P¹ that is a parity block included in the parity-check matrix of FIG. 4.

In the right side of FIG. 5, ‘−’ indicates a 38×38 zero matrix, and 0 indicates a 38×38 cyclic-permutation matrix S₀. A parity block P¹ illustrated in FIG. 5 includes zero cyclic-permutation matrices as elements at locations of (0, 0), (6, 0), and (11, 0) and locations of (m, m−1) and (m, m) in a range of 1≦m≦11. The parity block P¹ includes zero matrices at the other locations.

Since the aforementioned parity block P¹ can be used to embody a parallel processing LDPC encoder in units of partial blocks as a special case of a double diagonal parity block, it is possible to minimize the encoding complexity, when this type of parity block is used. That is, when the parity block P¹ satisfies a linearly independent condition, it is possible to use the parity block P¹. Particularly, when the parity block with a type illustrated in FIG. 5 is used, it is possible to embody an encoder with lower complexity.

Since the detailed contents of the double diagonal parity block is disclosed in a paper prepared by Richardson (‘Efficient Encoding of Low-Density Parity-Check Codes’, IEEE Trans. on Inform. Theory, Vol. 47, No. 2, February 2001), a detailed description thereof will be omitted.

FIGS. 6 to 10 respectively illustrate examples of first to five information blocks C¹₀, C¹₁, C¹₂, C¹₃, and C¹₄ of FIG. 4.

Integers that are largely represented in the right sides of FIGS. 6 to 10 indicate cyclic-permutation matrices obtained by cyclically shifting the 38×38 identity matrix by the integers in the right side. As described in relation to FIG. 5, ‘−’ indicates a 38×38 zero matrix. For example, in FIG. 6, 37¹ indicates a cyclic-permutation matrix S₃₇.

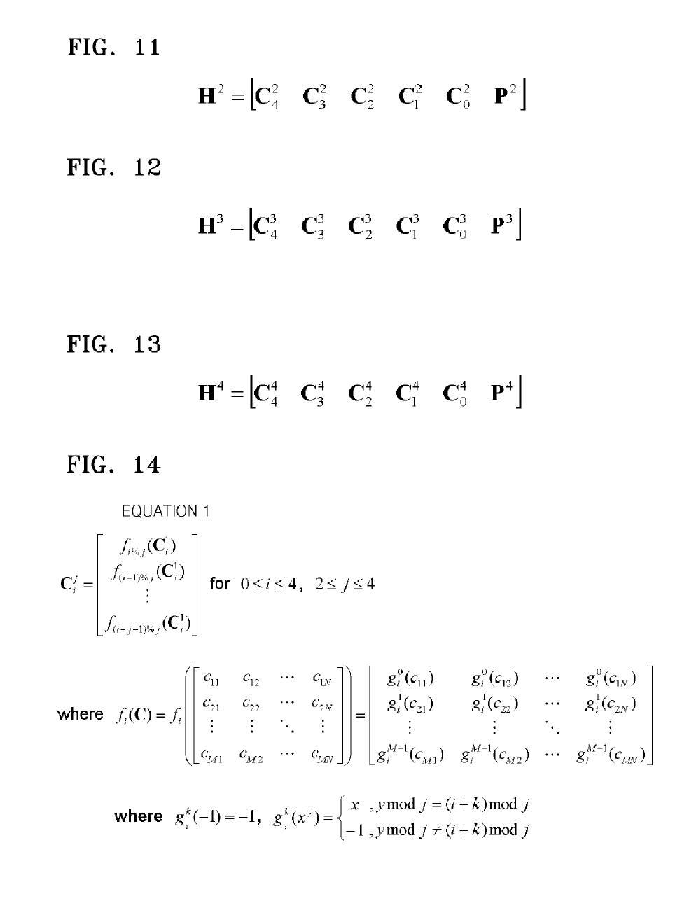

In addition, exponents in the right sides of FIGS. 6 to 10 are used to generate information blocks included in the parity-check matrices H², H³, and H⁴ respectively illustrated in FIGS. 11 to 13 by applying a row-splitting technique to first to fifth information blocks of FIG. 4 according to an embodiment of the present invention. This row-splitting technique will be described later with reference to Equation 1.

A parity-check matrix [C¹₀ P¹] constructed with the first information block C¹₀ illustrated in FIG. 6 and the parity block P¹ illustrated FIG. 5 is used to encode/decode the LDPC code with information length of 456 bits and a code rate of 0.5.

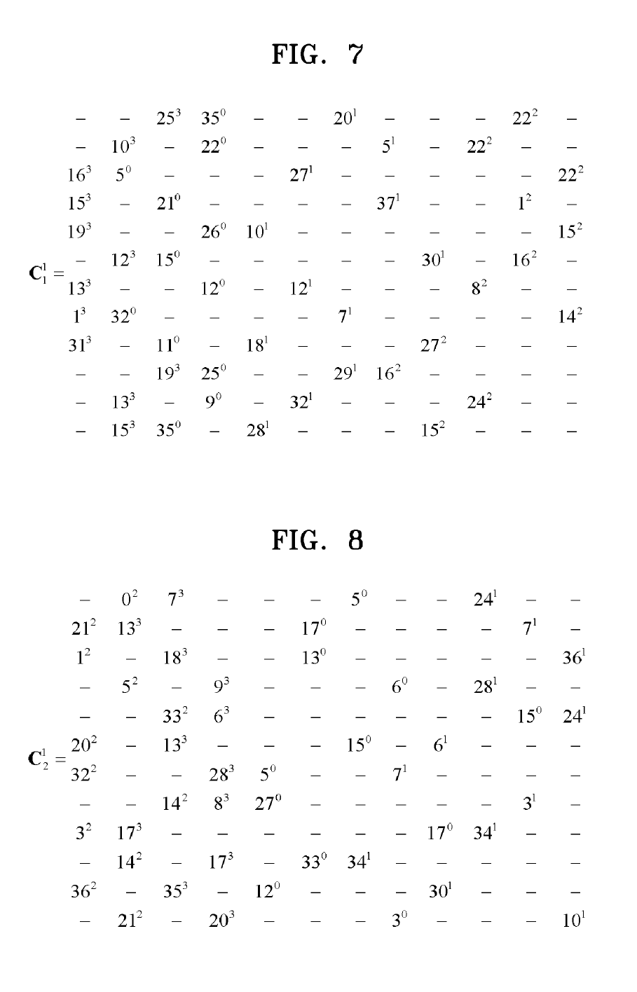

Similarly, a parity-check matrix [C¹₁ C¹₀ P¹] constructed with the first and second information blocks C¹₀ and C¹₁ respectively illustrated in FIGS. 6 and 7 and the parity block P¹ illustrated in FIG. 5 is used to encode/decode the LDPC code with information length of 912 bits and a code rate of ⅔.

Similarly, a parity-check matrix [C¹₂ C¹₁ C¹₀ P¹] constructed with the first to third information blocks C¹₀, C¹₁, and C¹₂ respectively illustrated in FIGS. 6 to 8 and the parity block P¹ illustrated in FIG. 5 is used to encode/decode the LDPC code with information length of 1368 bits and a code rate of ¾.

Similarly, a parity-check matrix [C¹₃ C¹₂ C¹₁ C¹₀ P¹] constructed with the first to fourth information blocks C¹₀, C¹₁, C¹₂, and C¹₃ respectively illustrated in FIGS. 6 to 9 and the parity block P¹ illustrated in FIG. 5 is used to encode/decode the LDPC code with information length of 1824 bits and a code rate of ⅘.

Similarly, a parity-check matrix [C¹₄ C¹₃ C¹₂ C¹₁ C¹₀ P¹] constructed with the first to fifth information blocks C¹₀, C¹₁, C¹₂, C¹₃, and C¹₄ respectively illustrated in FIGS. 6 to 10 and the parity block P¹ illustrated in FIG. 5 is used to encode/decode the LDPC code with information length of 2280 bits and a code rate of ⅚.

On the other hand, the matrices of FIGS. 5 to 10 are exemplary matrices used to describe the spirit and scope of the present invention. It will be sufficiently understood by those of ordinary skill in the art that it is possible to generate various matrices with the sizes of the matrices of FIGS. 5 to 10, in addition to the matrices shown in FIGS. 5 to 10 by optimization of degree distribution and cycle distribution.

FIGS. 11 to 13 respectively illustrate examples of parity-check matrices with 912, 1368, and 1824 bits which support five code rates. FIGS. 11 to 13 respectively illustrate the parity-check matrices H², H³, and H⁴ of FIG. 3.

The information blocks of the parity-check matrices H², H³, and H⁴ are generated by applying the row-splitting technique exemplified by Equation 1 to the information blocks of the parity-check matrix H¹. That is, an information block C^{j}ᵢ (here, j=2, 3, and 4, and i=0, 1, 2, 3, and 4) is obtained by applying the row-splitting technique to C¹ⱼ. For example, an information block C³₂ of FIG. 12 is obtained by applying the row-splitting technique to an information block C¹₂.

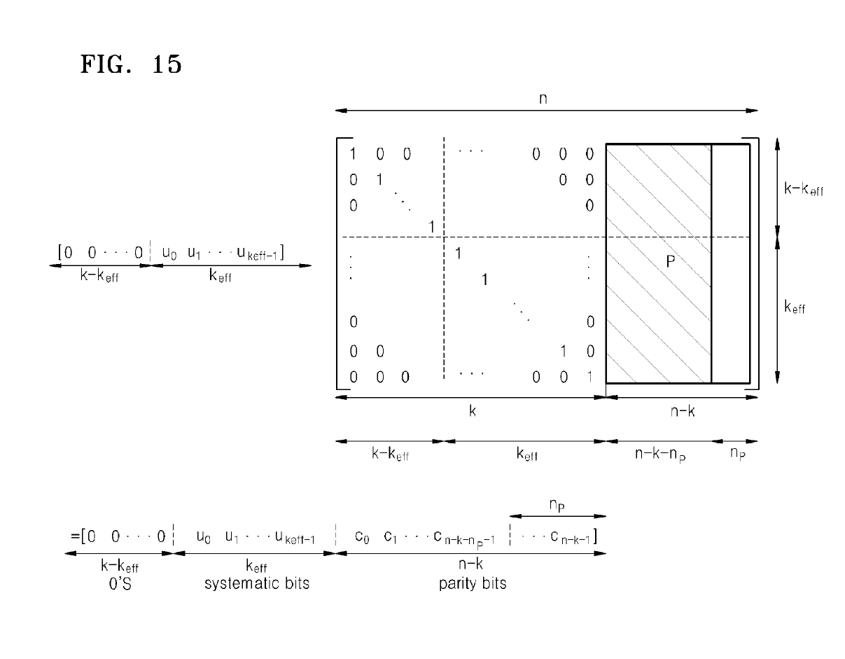

In addition, the parity blocks of the parity-check matrices H², H³, and H⁴ are generated by extending the parity block of the parity-check matrix H¹ while maintaining the structure thereof. That is, the parity block P² of FIG. 11 includes zero cyclic-permutation matrices at locations of (0, 0), (12, 0), and (23, 0) and locations of (m, m−1) and (m, m) in a range of 1≦m≦23 as elements. The parity block P² includes zero matrices at the other locations. Accordingly, the parity block P² of FIG. 11 has the same structure as the parity block P¹ illustrated in FIG. 5. In addition, the parity block P³ of FIG. 12 includes zero cyclic-permutation matrices at locations of (0, 0), (18, 0), and (35, 0) and locations of (m, m−1) and (m, m) in a range of 1≦m≦35 as elements. The parity block P³ includes zero matrices at the other locations. Accordingly, the parity block P³ of FIG. 12 has the same structure as the parity block P¹ illustrated in FIG. 5. Similarly, the parity block P⁴ of FIG. 13 includes zero cyclic-permutation matrices at locations of (0, 0), (24, 0), and (47, 0) and locations of (m, m−1) and (m, m) in a range of 1≦m≦47 as elements. The parity block P⁴ includes zero matrices at the other locations. Accordingly, the parity block P⁴ of FIG. 13 has the same structure as the parity block P¹ illustrated in FIG. 5.

The parity-check matrices [C²₀ P²], [C²₁ C²₀ P²], [C²₂ C²₁ C²₀ P²], [C²₃ C²₂ C²₁ C²₀ P²], [C³₀ P³], etc., obtained in the aforementioned procedure can support corresponding information lengths and corresponding code rates illustrated in FIG. 2.

As described above, the exponents of FIGS. 6 to 10 are used to generate information blocks of the parity-check matrices H², H³, and H⁴ by applying the row-splitting technique to the information blocks of the parity-check matrix H¹. The row-splitting technique according to an embodiment of the present invention is performed by using Equation 1 of FIG. 14.

FIG. 14 illustrates Equation 1 which represents a row-splitting technique according to an embodiment of the present invention. In Equation 1, a value of ‘−1’ in g^{k}ᵢ (−1)=−1 represents a zero sub-matrix.

In addition, in Equation 1, cₘₙ (here, m=1 to M, and n=1 to N) indicates sub-matrices located at a location of (m, n) of an information block constructed with M×N numbers of sub matrices. When C of fᵢ(C) of Equation 1 is the information block C¹₀ shown in FIG. 6, M=12, N=12, and c₁₂ is 27⁰.

As described above, there are three embodiments for designing the LDPC code with a variable information length and a variable code rate. In an embodiment A, a new parity-check matrix that is different from the parity-check matrix in the information length or code rate is generated by adding a second information block to the parity-check matrix constructed with the first information block and the parity block. In an embodiment B, when there is a parity-check matrix constructed with a basic information block and a basic parity block, a new parity-check matrix that is different from the basic parity-check matrix in the information length or code rate is generated by generating an extended information block by applying the row-splitting technique to the basic information block and an extended parity block with the same structure as the basic parity block by extending the basic parity block. An embodiment C is obtained by combining the embodiment A with the embodiment B.

In the specification, for convenience of explanation, the information block to which the row-splitting technique is applied is referred to as a basic information block, the information block obtained as the result of row-splitting is referred to as an extended information block. In addition, in the specification, for convenience of explanation, the parity block to be extended is referred to as a basic parity block, and the parity block obtained as the result of extension is referred to as an extended parity block.

The embodiment A will be additionally described as follows. While the parity-check matrices are generated by extending an information block in a state where the parity block is fixed, the information block is extended so as to generate a parity-check matrix with a high quality in degree distribution and cycle distribution.

The embodiment B will be additionally described as follows. An extended parity-check matrix that is different from the basic parity-check matrix is generated by the row-splitting of the information block included in the basic parity-check matrix. Here, a row-splitting technique is applied for generating a parity-check matrix with high quality degree distribution and cycle distribution.

On the other hand, in the specification, although the embodiments A, B, and C are described as cases where a large-sized parity-check matrix is generated from small-sized parity-check matrices, it will be sufficiently understood by those of ordinary skill in the art that the inverse procedure is also possible. That is, in the case of the embodiment A, there may exist a method of generating a large-sized parity-check matrix and generating a small-sized parity-check matrix by partially removing information blocks from the generated large-sized parity-check matrix. In addition, in the case of the embodiment B, it is possible to generate a reduced parity-check matrix corresponding to the aforementioned extended parity-check matrix by generating a large-sized basic parity-check matrix, applying a row combining technique that is the inverse procedure of the row-splitting technique to the information block of the generated basic parity-check matrix, and applying parity part switching that uses only a part of the parity block of the generated basic parity-check matrix. Here, the row combining with respect to the information block may be represented as parity combining of an information part. The parity part switching may be represented as parity combining of a parity part.

On the other hand, it may be also possible to design an LDPC code that supports more various information lengths and code rates by applying an information shortening technique and a puncturing technique to the method according to an embodiment of the present invention which designs the aforementioned LDPC code with the variable information length and the variable code rate.

FIG. 15 illustrates a concept whereby an information shortening technique and a puncturing technique are applied to a parity-check matrix. Specifically, there is described an example in which the information shortening by k−k_{eff} bits and the puncturing with respect to nₚ numbers of parity bits are applied to a k×n parity-check matrix shown in the right uppermost part of FIG. 15. Here, the k×n parity-check matrix basically supports a code rate of k/n and an information length of k.

A left uppermost vector that is a k×1 input message vector includes information words, which are constructed with k_{eff} numbers of information bits, and k−k_{eff} numbers of 0's which are filled with information shortenings, that is, the information length according to the current embodiment is k_{eff}. An n-bit codeword is generated by multiplying the input message vector by the parity-check matrix. Then, nₚ numbers of parity bits are punctured in the generated codeword. In addition, the aforementioned filled k−k_{eff} numbers of 0's are also deleted. As a result, the length of the codeword is finally n−k+k_{eff}−nₚ. Accordingly, in this case, it is possible to provide an information length of k_{eff} and a code rate k_{eff}/(n−k+k_{eff}−nₚ) which are respectively different from the information length of k and the code rate of k/n that are basically provided by the parity-check matrix.

On the other hand, although FIG. 15 illustrates a case where the information shortening technique and the puncturing technique with respect to the parity bits are applied, there may exist an embodiment in which only the information shortening technique is used and an embodiment in which the puncturing technique is used for the information bit, in addition to the aforementioned embodiment. Accordingly, it is possible to support more various information lengths and code rates by effectively using the embodiments.

In addition, in the aforementioned description, there has been described the method of performing the information shortening technique and the puncturing technique without modifying the parity-check matrix by performing zero padding before multiplying the input message vector by the parity-check matrix and by performing the puncturing technique after multiplying the input message vector by the parity-check matrix. However, there may also exist a method of generating a parity-check matrix with a new size of k_{eff}×(n−k+k_{eff}−nₚ) by applying the information shortening technique and the puncturing technique to the parity-check matrix and generating a codeword with a codeword length of n−k+k_{eff}−nₚ by multiplying the generated parity-check matrix by the input message vector with the information length k_{eff}×1, in addition to the aforementioned method. In the latter method, a parity-check matrix with a size k_{eff}×(n−k+k_{eff}−nₚ) is obtained by removing keff numbers of leftmost columns, np numbers of rightmost columns, and k_{eff} numbers of uppermost rows from the k×n parity-check matrix.

Since those of ordinary skill in the art can easily perform encoding/decoding for the LDPC code suggested in the present invention by applying various known encoding/decoding techniques of the LDPC code, a detailed description of the encoding/decoding procedure will be omitted.

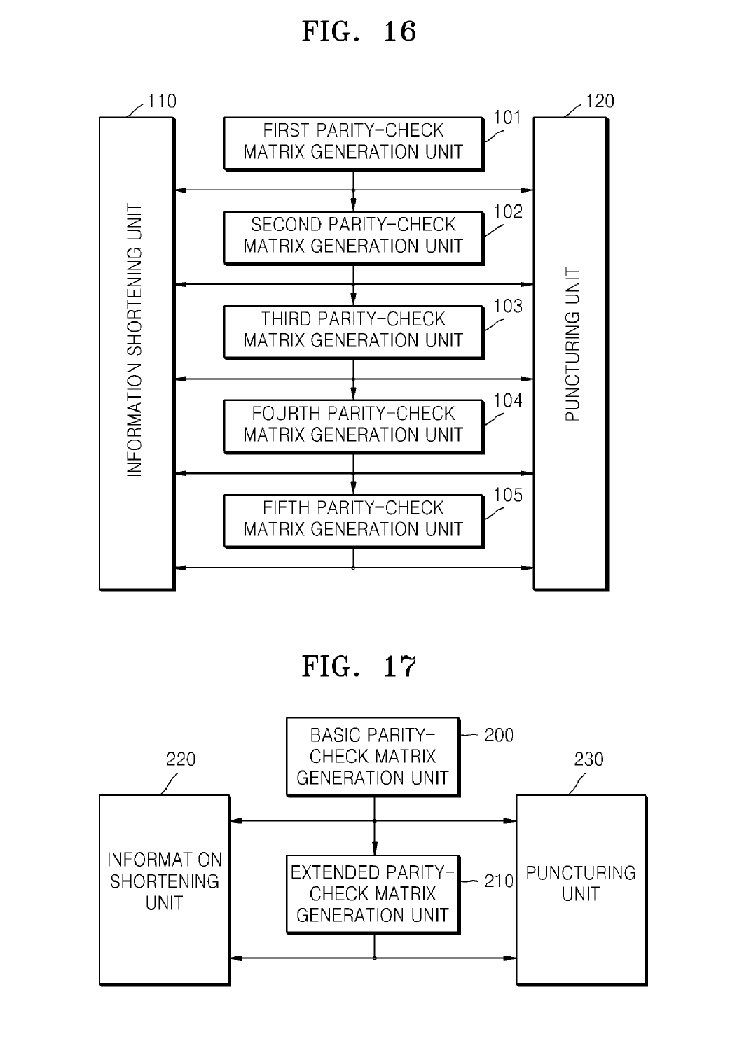

FIG. 16 is a block diagram illustrating a structure of an apparatus for generating a parity-check matrix according to an embodiment of the present invention. The apparatus for generating a parity-check matrix includes a first parity-check matrix generation unit 101, a second parity-check matrix generation unit 102, a third parity-check matrix generation unit 103, a fourth parity-check matrix generation unit 104, a fifth parity-check matrix generation unit 105, an information shortening unit 110, and a puncturing unit 120.

The embodiment of FIG. 16 will be described as follows with reference to FIGS. 4 to 10.

The first parity-check matrix generation unit 101 generates a first parity-check matrix [C¹₀ P¹] constructed with the first information block C¹₀ shown in FIG. 6 and the parity block P¹ shown in FIG. 5.

The second parity-check matrix generation unit 102 generates a second parity-check matrix [C¹₁ C¹₀ P¹] by adding the second information block C¹₁ of FIG. 7 to the generated first parity-check matrix [C¹₀ P¹].

The third parity-check matrix generation unit 103 generates a third parity-check matrix [C¹₂ C¹₁ C¹₀ P¹] by adding the third information block C¹₂ of FIG. 8 to the generated second parity-check matrix [C¹₁ C¹₀ P¹].

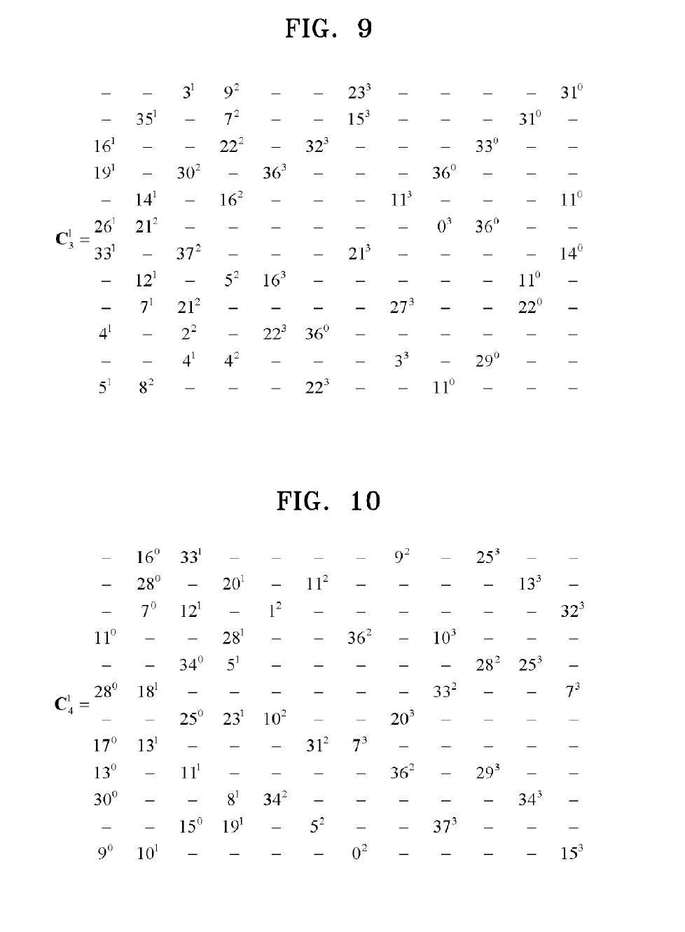

The fourth parity-check matrix generation unit 104 generates a fourth parity-check matrix [C¹₃ C¹₂ C¹₁ C¹₀ P¹] by adding the fourth information block C¹₃ of FIG. 9 to the generated third parity-check matrix [C¹₂ C¹₁ C¹₀ P¹].

The fifth parity-check matrix generation unit 105 generates a fifth parity-check matrix [C¹₄ C¹₃ C¹₂ C¹₁ C¹₀ P¹] by adding the fifth information block C¹₄ of FIG. 10 to the generated fourth parity-check matrix [C¹₃ C¹₂ C¹₁ C¹₀ P¹].

The information shortening unit 110 generates at least one parity-check matrix different from the first to fifth parity-check matrices by applying the information shortening technique to at least one of the first to fifth parity-check matrices.

The puncturing unit 120 generates at least one parity-check matrix different form the first to fifth parity-check matrices by applying the puncturing technique to at least one of the first through fifth parity-check matrices.

FIG. 17 is a block diagram illustrating a structure of an apparatus for generating a parity-check matrix according to another embodiment of the present invention. The apparatus for generating a parity-check matrix includes a basic parity-check matrix generation unit 200, an extended parity-check matrix generation unit 210, an information shortening unit 220, and a puncturing unit 230.

The embodiment of FIG. 17 represents an embodiment in which the parity-check matrices H², H³, and H⁴ respectively illustrated in FIGS. 11 to 13 are generated from the parity-check matrix H¹ of FIG. 4.

Although the basic parity-check matrix generation unit 200 generates at least one parity-check matrix, for convenience of explanation, the embodiment of FIG. 16 will be described with the assumption that a basic parity-check matrix [C¹ P¹] is generated.

The extended parity-check matrix generation unit 210 generates an information block C² by applying the row-splitting technique to an information block C¹ of the basic parity-check matrix [C¹ P¹] and generates a parity block P² with the same structure as the parity block P¹ by extending the parity block P¹ of the basic parity-check matrix [C¹ P¹]. As a result, an extended parity-check matrix [C² P²] is generated.

The information shortening unit 220 generates at least one parity-check matrix, which is different from the basic parity-check matrix [C¹ P¹] and the extended parity-check matrix [C² P²], by applying information shortening to at least one of the basic parity-check matrix [C¹ P¹] and the extended parity-check matrix [C² P²].

The puncturing unit 230 generates at least one parity-check matrix, which is different from the basic parity-check matrix [C¹ P¹] and the extended parity-check matrix [C² P²], by applying the puncturing technique to at least one of the basic parity-check matrix [C¹ P¹] and the extended parity-check matrix [C² P²].

On the other hand, when the basic parity-check matrix generation unit 200 generates the first to fifth basic parity-check matrices [C¹₀ P¹], [C¹₁ C¹₀ P¹], [C¹₂ C¹₁ C¹₀ P¹], [C¹₃ C¹₂ C¹₁ C¹₀ P¹], and [C¹₄ C¹₃ C¹₂ C¹₁ C¹₀ P¹] (that is, when the basic parity-check matrix generation unit 200 generates a plurality of basic parity-check matrices), the extended parity-check matrix generation unit 210 can generate extended parity-check matrices [C²₀ P²], [C²₁ C²₀ P²], [C²₂ C²₁ C²₀ P²], [C²₃ C²₂ C²₁ C²₀ P²], and [C²₄ C²₃ C²₂ C²₁ C²₀ P²] from the first to fifth basic parity-check matrices.

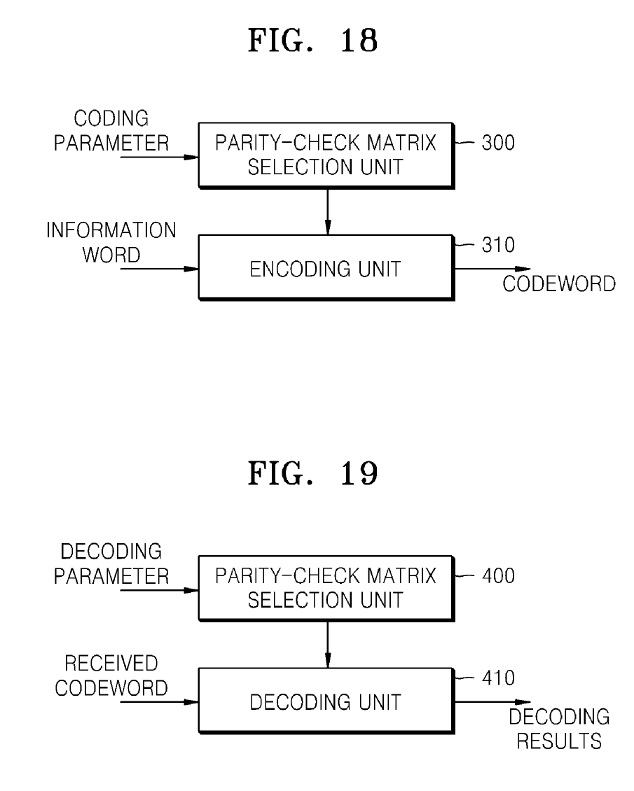

FIG. 18 is a block diagram illustrating an LDPC encoding apparatus which supports a variable information length and a variable code rate according to an embodiment of the present invention. The LDPC encoding apparatus includes a parity-check matrix selection unit 300 and an encoding unit 310.

The parity-check matrix selection unit 300 selects a parity-check matrix corresponding to an input encoding parameter from among a plurality of parity-check matrices. Here, the plurality of parity-check matrices indicate parity-check matrices generated as described in FIGS. 16 and 17. Here, the input encoding parameter is used to select a parity-check matrix. Examples of the input encoding parameter include an information length and a code rate. However, since the input encoding parameter has only to enable determination of a parity-check matrix, the input encoding parameter does not have to be limited to the aforementioned examples.

The encoding unit 310 encodes an input information word based on the selected parity-check matrix.

FIG. 19 is a block diagram illustrating an LDPC decoding apparatus which supports a variable information length and a variable code rate according to an embodiment of the present invention. The LDPC decoding apparatus includes a parity-check matrix selection unit 400 and a decoding unit 410.

The parity-check matrix selection unit 400 selects a parity-check matrix corresponding to an input decoding parameter from among a plurality of parity-check matrices. Here, the plurality of parity-check matrices indicate parity-check matrices generated as described in FIGS. 16 and 17. Here, the input decoding parameter is used to select a parity-check matrix. Examples of the input decoding parameter include a code rate and an information length of a received codeword. However, since the input decoding parameter has only to determine a parity-check matrix, the input decoding parameter does not have to be limited to the aforementioned examples.

The decoding unit 410 decodes the received codeword based on the selected parity-check matrix. An example of a decoding algorithm is a message passing algorithm (MPA). On the other hand, when the selected parity-check matrix is a matrix to which the information shortening technique is applied, the decoding unit 410 sets a probability that the information shortening bit has a value of 0 to 1 and performs decoding. When the selected parity-check matrix is a matrix to which the puncturing technique is applied and when decoding based on the MPA is initially performed, the decoding unit 410 sets a probability that the punctured bit has a value of 1 to 0.5 and starts decoding.

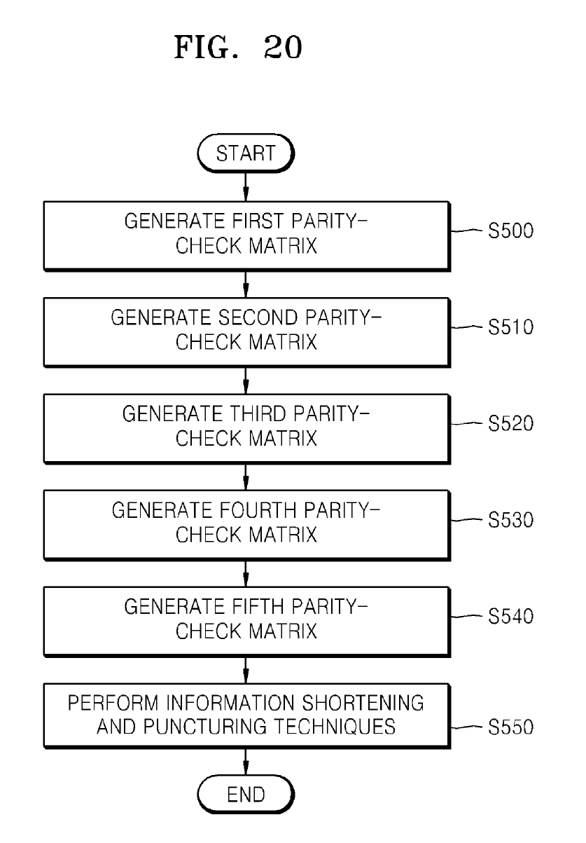

FIG. 20 is a flowchart illustrating a method of generating a parity-check matrix according to an embodiment of the present invention.

Referring to FIG. 20, the method of generating a parity-check matrix according to the current embodiment includes a sequence of processes performed by the apparatus for generating a parity-check matrix of FIG. 16. Accordingly, although a detailed description is omitted, the aforementioned description of the apparatus for generating a parity-check matrix of FIG. 16 also applies to the method of generating a parity-check matrix according to the embodiment.

The embodiment of FIG. 20 will be described as follows with reference to FIG. 16.

In operation S500, the first parity-check matrix generation unit 101 generates a first parity-check matrix constructed with the first information block and the parity block.

In operation S510, the second parity-check matrix generation unit 102 generates a second parity-check matrix by adding the second information block to the generated first parity-check matrix.

In operation S520, the third parity-check matrix generation unit 103 generates a third parity-check matrix by adding the third information block to the generated second parity-check matrix.

In operation S530, the fourth parity-check matrix generation unit 104 generates a fourth parity-check matrix by adding the fourth information block to the generated third parity-check matrix.

In operation S540, the fifth parity-check matrix generation unit 105 generates a fifth parity-check matrix by adding the fifth information block to the generated fourth parity-check matrix.

In operation S550, the information shortening unit 110 and the puncturing unit 120 generate at least one parity-check matrix that is different from the first to fifth parity-check matrices by respectively applying the information shortening and puncturing techniques to at least one of the first to fifth parity-check matrices.

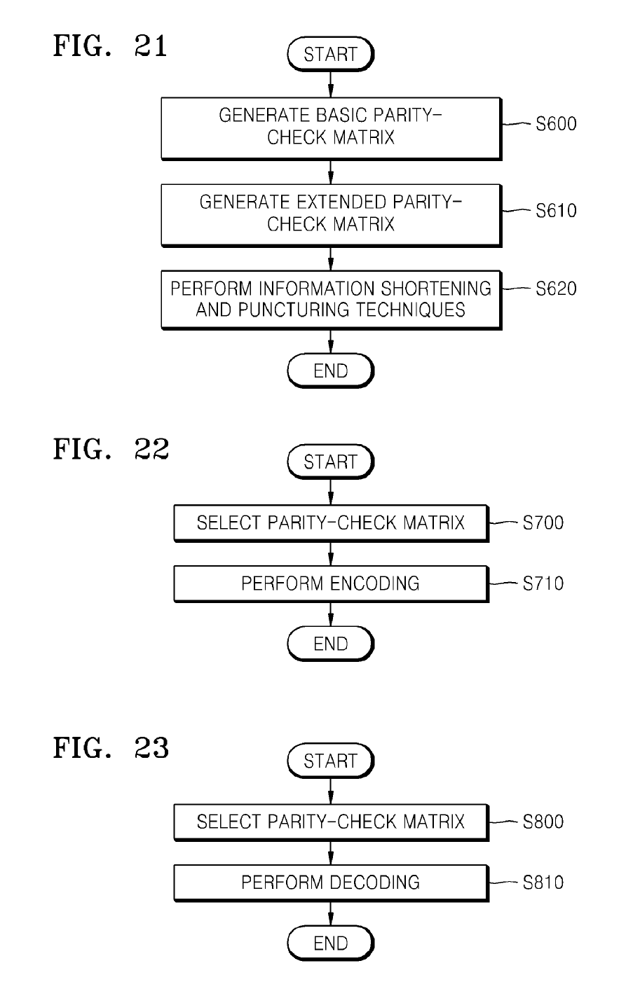

FIG. 21 is a flowchart illustrating a method of generating a parity-check matrix according to another embodiment of the present invention.

Referring to FIG. 21, the method of generating a parity-check matrix according to the current embodiment includes a sequence of processes performed by the apparatus for generating a parity-check matrix of FIG. 17. Accordingly, although a detailed description is omitted, the aforementioned description of the apparatus for generating a parity-check matrix of FIG. 17 also applies to the method of generating a parity-check matrix according to the embodiment.

The embodiment of FIG. 21 will be described as follows with reference to FIG. 17.

In operation S600, the basic parity-check matrix generation unit 200 generates at least one parity-check matrix.

In operation S610, the extended parity-check matrix generation unit 210 generates at least one extended parity-check matrix by applying the row-splitting technique to an information block of the basic parity-check matrix and extending the parity block of the basic parity-check matrix.

In operation S620, the information shortening unit 220 and the puncturing unit 230 generate at least one parity-check matrix, which is different from the basic parity-check matrix and the extended parity-check matrix, by respectively applying the information shortening and puncturing techniques to at least one of the basic parity-check matrix and the extended parity-check matrix.

FIG. 22 is a flowchart illustrating an LDPC encoding method which supports a variable information length and a variable code rate according to an embodiment of the present invention.

Referring to FIG. 22, the method of generating a parity-check matrix according to the current embodiment includes a sequence of processes performed by the LDPC encoding apparatus which supports a variable information length and a variable code rate of FIG. 18. Accordingly, although a detailed description is omitted, the aforementioned description of the LDPC encoding apparatus which supports a variable information length and a variable code rate of FIG. 18 also applies to the method of generating a parity-check matrix according to the current embodiment.

The embodiment of FIG. 22 will be described as follows with reference to FIG. 18.

In operation S700, the parity-check matrix selection unit 300 selects a parity-check matrix corresponding to an input encoding parameter from among a plurality of parity-check matrices. Here, the plurality of parity-check matrices indicate parity-check matrices generated as described in FIGS. 16 and 17.

In operation S710, the encoding unit 310 encodes an input information word based on the selected parity-check matrix.

FIG. 23 is a flowchart illustrating an LDPC decoding method which supports a variable information length and a variable code rate according to an embodiment of the present invention.

Referring to FIG. 23, the method of generating a parity-check matrix according to the current embodiment includes a sequence of processes performed by the LDPC decoding apparatus which supports a variable information length and a variable code rate of FIG. 19. Accordingly, although a detailed description is omitted, the aforementioned description of the LDPC decoding apparatus which supports a variable information length and a variable code rate of FIG. 19 also applies to the method of generating a parity-check matrix according to the current embodiment.

The embodiment of FIG. 23 will be described as follows with reference to FIG. 19.

In operation S800, the parity-check matrix selection unit 400 selects a parity-check matrix corresponding to an input decoding parameter from among a plurality of parity-check matrices. Here, the plurality of parity-check matrices indicate parity-check matrices generated as described in FIGS. 16 and 17.

In operation S810, the decoding unit 410 decodes the received codeword based on the selected parity-check matrix.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion. Also, functional programs, codes, and code segments for accomplishing the present invention can be easily construed by programmers of ordinary skill in the art to which the present invention pertains.

While the present invention has been particularly shown and described with reference to exemplary embodiments thereof, it will be understood by those of ordinary skill in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

1. A method of generating a parity-check matrix of an LDPC (low density parity-check) code with a variable information length and a variable code rate, the method comprising:
a first parity-check matrix generation process of generating a first parity-check matrix constructed with a first information block and a parity block; and
an m-th parity-check matrix generation process of generating an m-th parity-check matrix by adding an m-th information block to a generated (m−1)-th parity-check matrix (1<m≦M, where M is a natural number equal to or greater than two).

2. The method of claim 1, wherein the m-th (1≦m≦M) parity-check matrix generation process includes a process of generating the m-th parity-check matrix by performing optimization of degree distribution and cycle distribution.

3. The method of claim 1, further comprising an information shortening process of generating at least one parity-check matrix which is different from the first to M-th parity-check matrices by applying an information shortening technique to at least one of the first to M-th parity-check matrices.

4. The method of claim 1, further comprising a puncturing process of generating at least one parity-check matrix which is different from the first to M-th parity-check matrices by applying a puncturing technique to at least one of the first to M-th parity-check matrices.

5. The method of claim 4, wherein the puncturing process includes a process of performing the puncturing technique with respect to an information block or the parity block.

6. A method of generating a parity-check matrix of an LDPC (low density parity-check) code with a variable information length and a variable code rate, the method comprising:
a basic parity-check matrix generation process of generating at least one basic parity-check matrix; and
an extended parity-check matrix generation process of generating at least one extended parity-check matrix by applying a row-splitting technique to an information block of the basic parity-check matrix and extending a parity block of the basic parity-check matrix.

7. The method of claim 6,
wherein the basic parity-check matrix generation process includes a process of generating an m-th basic parity-check matrix by generating the first basic parity-check matrix constructed with a first basic information block and a basic parity block and by adding an m-th basic information block to a generated (m−1)-th basic parity-check matrix (1<m≦M, where M is a natural number equal to or greater than two), and
wherein the extended parity-check matrix generation process includes a process of generating an m-th extended information block constructed with an extended parity block and first to m-th extended information blocks by generating an extended parity block by extending the basic parity block and by generating the m-th extended information block by applying the row-splitting technique to the m-th basic information block (1≦m≦M).

8. The method of claim 6, wherein the extended parity-check matrix generation process includes a process of generating the extended parity block with the same structure as the basic parity block.

9. The method of claim 6, wherein the basic parity block and the extended parity block have a double diagonal matrix form.

10. The method of claim 6,
wherein the basic parity-check matrix generation process includes a process of generating the basic parity-check matrix by performing optimization of degree distribution and cycle distribution, and
wherein the extended parity-check matrix generation process includes a process of generating the extended parity-check matrix by performing the optimization of the degree distribution and the cycle distribution.

11. The method of claim 6, further comprising an information shortening process of generating at least one parity-check matrix which is different from the basic parity-check matrix and the extended parity-check matrix by applying an information shortening technique to at least one of the basic parity-check matrix and the extended parity-check matrix.

12. The method of claim 6, further comprising a puncturing process of generating at least one parity-check matrix which is different from the basic parity-check matrix and the extended parity-check matrix by applying a puncturing technique to at least one of the basic parity-check matrix and the extended parity-check matrix.

13. The method of claim 12, wherein the puncturing process includes a process of performing the puncturing technique with respect to an information block or the parity block.

14. An LDPC encoding method which supports a variable information length and a variable code rate, the LDPC encoding method comprising:
a parity-check matrix selection process of selecting a parity-check matrix corresponding to an input encoding parameter from among a plurality of parity-check matrices; and
an encoding process of encoding an input information word based on the selected parity-check matrix.

15. The LDPC encoding method of claim 14, wherein the input encoding parameter includes a code rate and a length of the input information word.

16. The LDPC encoding method of claim 14, wherein the plurality of parity-check matrices include a first parity-check matrix, which is constructed with a first information block and a parity block, and an m-th parity-check matrix, which is obtained by adding an m-th information block to an (m−1)-th parity-check matrix (1<m≦M, where M is a natural number equal to or greater than two).

17. The LDPC encoding method of claim 14, wherein the plurality of parity-check matrices include at least one basic parity-check matrix and at least one extended parity-check matrix generated by applying a row-splitting technique to an information block of the basic parity-check matrix and extending a parity block of the basic parity-check matrix.

18. An LDPC decoding method which supports a variable information length and a variable code rate, the LDPC decoding method comprising:
a parity-check matrix selection process of selecting a parity-check matrix corresponding to an input decoding parameter from among a plurality of parity-check matrices; and
a decoding process of decoding a received codeword based on the selected parity-check matrix,
wherein the plurality of parity-check matrices include a first parity-check matrix, which is constructed with a first information block and a parity block, and an m-th parity-check matrix, which is obtained by adding an m-th information block to an (m−1)-th parity-check matrix (1<m≦M, where M is a natural number equal to or greater than two).

19. The LDPC decoding method of claim 18, wherein the input decoding parameter includes a code rate and a length of the received codeword.

20. The LDPC encoding method of claim 18,
wherein the plurality of parity-check matrices further include at least one parity-check matrix generated by applying the information shortening technique to at least one of the first to M-th parity-check matrices, and
wherein the decoding process includes a process of performing decoding by setting a probability that an information-shortened bit has a value of 0 to a value of 1, when the selected parity-check matrix is a matrix to which the information shortening technique is applied.

21. The LDPC encoding method of claim 18,
wherein the plurality of parity-check matrices further include at least one parity-check matrix generated by applying the puncturing technique to at least one of the first to M-th parity-check matrices, and
wherein the decoding process includes a process of performing decoding by setting a probability that a punctured bit has a value of 0 to a value of 0.5, when the selected parity-check matrix is a matrix to which the puncturing technique is applied.

22. An LDPC decoding method which supports a variable information length and a variable code rate, the LDPC decoding method comprising:
a parity-check matrix selection process of selecting a parity-check matrix corresponding to an input decoding parameter from among a plurality of parity-check matrices; and
an encoding process of decoding a received codeword based on the selected parity-check matrix,
wherein the plurality of parity-check matrices include at least one basic parity-check matrix and at least one extended parity-check matrix generated by applying a row-splitting technique to an information block of the basic parity-check matrix and extending a parity block of the basic parity-check matrix.

23. The LDPC decoding method of claim 22, wherein the input decoding parameter includes a code rate and a length of the received codeword.

24. The LDPC decoding method of claim 22,
wherein the plurality of parity-check matrices further include at least one parity-check matrix generated by applying the information shortening technique to at least one of the first to M-th parity-check matrices, and
wherein the decoding process includes a process of performing decoding by setting a probability that an information-shortened bit has a value of 0 to a value of 1, when the selected parity-check matrix is a matrix to which the information shortening technique is applied.

25. The LDPC decoding method of claim 22,
wherein the plurality of parity-check matrices further include at least one parity-check matrix generated by applying the puncturing technique to at least one of the first to M-th parity-check matrices, and
wherein the decoding process includes a process of performing decoding by setting a probability that a punctured bit has a value of 0 to a value of 0.5, when the selected parity-check matrix is a matrix to which the puncturing technique is applied.
